(19) United States
(12) Patent Application Publication
(10) Pub. No.: US 2006/0256980 A1
(43) Pub. Date: Nov. 16, 2006

(54) Method and apparatus for dynamically controlling threshold of onset of audio dynamics processing

(76) Inventor: Jason C. Pritchard, Las Vegas, NV (US)

Correspondence Address: BAKER & DANIELS LLP;111 E. WAYNE STREET, SUITE 800, FORT WAYNE, IN, 46802, US

(21) Appl. No.: 11/126,896

(22) Filed: May 11, 2005

(51) Int. Cl. H03G 3/00

(52) U.S. Cl. 381/104

(57) ABSTRACT

A method and apparatus for dynamically controlling the threshold of the onset of dynamics processing in an audio system is provided. In an audio system, the onset of dynamics processing is controlled by varying a control point. The control point is moved by an audio engineer or other means. By changing the position of the control point, the audio engineer is also changing the threshold of onset of dynamics processing, so as to provide a dynamic safety net. Thus, when the engineer moves the control point to a given position, the threshold of onset of dynamics processing moves to a new position which is proportional to the position of the control point, and effectively provides a window through which audio may exit the system unprocessed by the dynamics processor. Regardless of where the control point is positioned, the onset of dynamics processing will depend on the position of the control point and the amount of offset being applied to the threshold.

### BACKGROUND

1. Field of the Invention

The present invention relates to dynamics processors for audio signals, and, more particularly, to a method and apparatus for dynamically controlling the threshold of onset of dynamics processing. Dynamics processing relates to the use of compression, expansion, limiting, noise gating, dynamic equalization or other devices that relate to the processing of dynamic elements in an audio signal.

2. Description of the Prior Art

The dynamic range of an audio passage is the ratio of the loudest (undistorted) signal to the quietest (just audible) signal, expressed in decibels (dB). Usually the maximum output signal is restricted by the size of the power supplies, while the minimum output signal is fixed by the noise floor. Professional-grade analog signal processing equipment can output maximum levels of +26 dB, with the best noise floors being down around −94 dB. This gives a maximum dynamic range of 120 dB which can be very difficult to work with. Thus were born dynamics processors.

An audio compressor can be used to limit or reduce the dynamic content of an audio signal. In a live theater situation, the dynamic content of an amplified audio signal produced by an actor can be on the order of 40 dB or more. An audio engineer must keep an actor's amplified vocal level within an acceptable and comfortable range by actively controlling the level of the actor's microphone on the sound mixing console. The audio engineer must both anticipate and respond to rapidly changing dynamic content, and attempt to smooth the dynamic content of the signal for appropriate delivery to an audience. When the dynamic content changes rapidly, the peaks of the instantaneous loud material can exceed comfortable audio levels for the audience, thereby generating complaints about the sound being too loud. The audio engineer is essentially a “smart” compressor, by reducing the gain when the source is too loud and increasing the gain when the source is too quiet, this is known in the field as gain riding. Consistent, predictable delivery by the actor, along with familiarity by the engineer, can create a very smooth, natural sounding dynamic compression which keeps the average level of the signal within a 5 dB window centered around, for example, 75 dB.

Current tools and techniques are well suited for controlling all of the parameters of dynamic control; however, the use of compression in high gain live performance has several drawbacks. In a conventional system, compressors are designed such that the threshold is reasonably low to constantly compress the signal, i.e., fixed parameter compression. The threshold is set low enough so that the majority of the signal exceeds the threshold of the compressor, thereby reducing the overall gain of the signal. The use of fixed parameter compression can have the undesired effect of reducing the overall gain of the system by lowering the peak to average ratios. A subsequent increase in the average level of the signal reduces the headroom, i.e., the amount of usable gain before acoustic feedback occurs, of the system as a whole, and creates concerns about acoustic feedback within the audio system. Make-up gain may be added back to the signal after compression in such a situation, but at the risk of creating a very unstable sound system in a live theater situation with a number of live microphones on stage.

### SUMMARY

The present invention provides a method and apparatus for dynamically controlling the threshold of the onset of dynamics processing in an audio system. In an audio system, the onset of dynamics processing is controlled by varying the output of the system via a control point. The value of the control point is changed by an audio engineer or other means in response to the dynamics of the live presentation, or any other reason for purposes of creating the desired effect or mix levels. By changing the value of the control point, the audio engineer is also manipulating the value of the threshold of the onset of dynamics processing being applied to the audio signal, so as to provide a dynamic safety net. Thus, when the engineer moves the control point to a given position, the threshold of the onset of dynamics processing moves to a new position which is proportional to the position of the control point. The proportion to which the threshold of the onset of dynamics processing is related to the control point may be altered separately. For example, if the control point is at a given value, 0 dB, and the threshold of the onset of dynamics processing is offset from the control point by +5 dB, when the control point's value is changed to −10 dB, the threshold of the onset of dynamics processing would be proportionally changed to −5 dB. Thus, regardless of where the control point is positioned, the threshold of the onset of dynamics processing will be determined by the position of the control point, and the amount of threshold offset. Additionally, the audio signal which is to be processed by the dynamics processor must reach the dynamics processor after it has passed through the control point from which threshold control is derived.

In one embodiment, the present invention provides a method for dynamically controlling a threshold of onset of dynamics processing including the steps of controlling a level of an audio signal, inputting the level of the audio signal into an audio dynamics processor, and determining the threshold of onset of dynamics processing based on the level.

In another embodiment, the present invention provides a dynamically-controlled threshold system for dynamically controlling a threshold of onset of dynamics processing including an audio mixing console including a control point and a dynamics processor in communication with the control point, the dynamics processor having the threshold of onset of dynamics processing controlled by the control point.

In yet another embodiment, the present invention provides a dynamically-controlled threshold system for dynamically controlling a threshold of onset of dynamics processing including means for controlling a level of an audio signal, means for inputting the level of the audio signal into an audio dynamics processor, and means for determining the threshold of onset of dynamics processing based on the level.

### BRIEF DESCRIPTION OF THE DRAWINGS

The above mentioned and other features and objects of this invention, and the manner of attaining them, will become more apparent and the invention itself will be better understood by reference to the following description of exemplary embodiments of the invention taken in conjunction with the accompanying drawings, wherein:

FIG. 1 is a schematic diagram of the dynamically controlled audio dynamics processor threshold system of the present invention; and

FIG. 2 is a schematic diagram of an alternative embodiment of the dynamically controlled audio dynamics processor threshold system of the present invention.

Corresponding reference characters indicate corresponding parts throughout the several views. Although the drawings represent embodiments of the present invention, the drawings are not necessarily to scale and certain features may be exaggerated in order to better illustrate and explain the present invention. The exemplifications set out herein illustrate embodiments of the invention, and such exemplifications are not to be construed as limiting the scope of the invention in any manner.

### DETAILED DESCRIPTION

The embodiments disclosed below are not intended to be exhaustive or limit the invention to the precise forms disclosed in the following detailed description. Rather, the embodiments are chosen and described so that others skilled in the art may utilize their teachings.

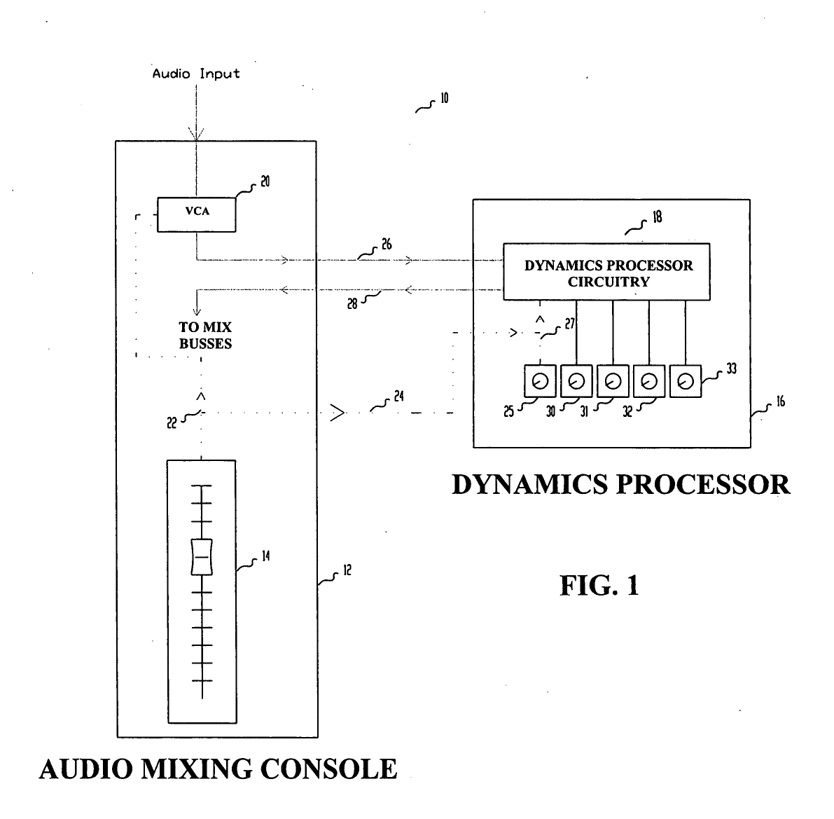

Referring now to FIG. 1, threshold system 10 is shown including audio mixing console 12 and dynamics processor 16. In one embodiment, dynamics processor 16 is an audio compressor. Audio input enters audio mixing console 12 and is manipulated by control point 14. In one embodiment, control point 14 may be a channel fader. Control point 14 is controlled by an audio engineer to vary a control signal which is fed to voltage controlled amplifier (VCA) 20. Output from control point 14 is input into VCA 20 via control path 22. In one embodiment, control path 22 is a hardwired connection. In another embodiment, control path 22 may be a wireless connection.

Output from control point 14 is also input into dynamics processor 16 via control path 24. In one embodiment, control path 24 is a hardwired connection. In another embodiment, control path 24 may be a wireless connection. Control paths 24 and 22 could each be a voltage, resistance, capacitance, or derived from a value determined as a co-efficient in a digital signal processor (DSP). Control path 24 communicates to dynamics processor 16 the position of control point 14. Threshold control 25 of dynamics processor 16 may be set at a given value, which is combined as an offset with the position data received from control point 14, to determine the final threshold of the onset of dynamics processing, for example, threshold control 25 may set the threshold at +10 dB, which when treated as an offset, makes the final threshold +10 dB of the position of the control point 14. In one embodiment, the threshold is the point of onset of compression. Generally, if the output exceeds the threshold, compression is applied. Threshold control 25 sets the amount of offset to be applied to the data received from control point 14 to derive a final threshold value. The final threshold value is sent to dynamics processor circuitry 18 via control path 27. Dynamics processor circuitry 18 is provided with an audio signal to be processed from the audio mixing console 12 at a stage beyond VCA 20. All of FIG. 1 may comprise analog circuitry, DSP circuitry, or software code.

In operation, an input signal enters audio mixing console 12. Control point 14 is adjusted to control the level of output exiting threshold system 10. For example, control point 14 is used to increase the level of the audio output if the audio input is too quiet, or, alternatively, control point 14 is used to decrease the level of the audio output if the audio input is too loud. Control point 14 may be manually controlled by an audio engineer or automated and controlled by a computer or other means. Control point 14 communicates a control voltage to VCA 20. The input signal is amplified by VCA 20 corresponding to the manipulations of control point 14. The output from VCA 20 is then input into dynamics processor circuitry 18 via audio path 26.

Dynamics processor circuitry 18 analyzes the signal input via audio path 26 and determines if the signal output level exceeds the threshold of system 10. The threshold of system 10 is determined by two factors: the position of control point 14 and the setting of threshold control 25. Thus, as the level of the signal is changed by control point 14, the threshold of system 10 changes dynamically. If threshold control 25 is set for the threshold to be +10 dB, then the onset of compression will be at the position of the control point 14 plus 10 dB. For example, if the position of control point 14 is −5 dB and threshold control 25 is set at +10 dB, dynamics processor circuitry 18 will compress the signal output from VCA 20 if it exceeds +5 dB. If the position of control point 14 changes to −15 dB with threshold control 25 set at +10 dB, dynamics processor circuitry 18 will compress the signal output from VCA 20 if it exceeds −5 dB. The output from dynamics processor circuitry 18 is returned to audio mixing console 12 via audio path 28 after which the signal is fed to output busses for output to speakers or other output producing means.

Attack control 30 and release control 31 of dynamics processor 16 function to determine how quickly compression is applied to the signal and how quickly compression is released, respectively, and are well known in the art. Ratio control 32 sets the compression ratio of dynamics processor 16, which, in one embodiment, is a 2:1 ratio wherein for every 1 dB the input increases, the output of dynamics processor 16 is only going to increase by ½ dB. Gain control 33 is essentially used only for make-up gain, which is gain added back to the signal after compression.

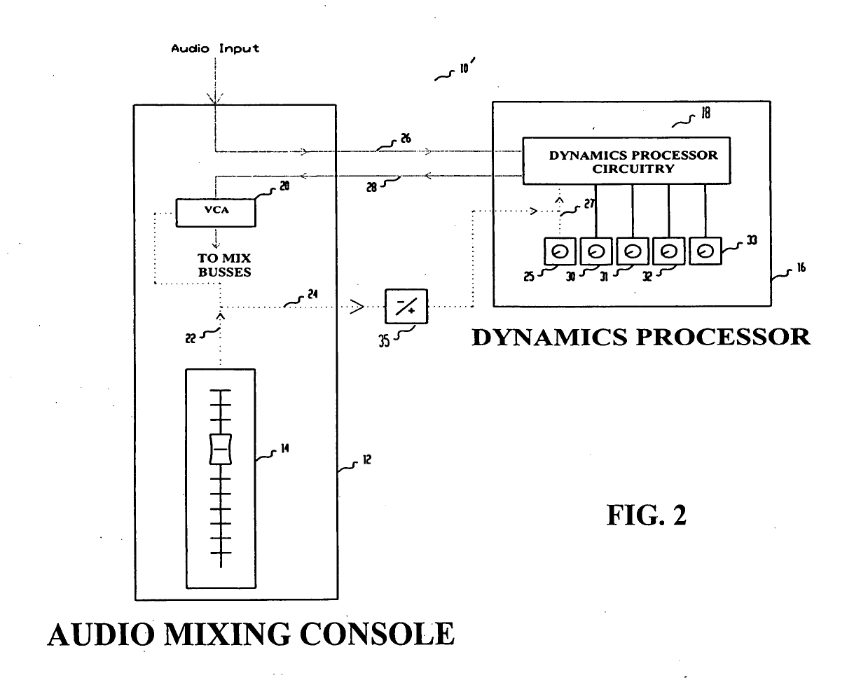

Referring now to FIG. 2, an alternative embodiment threshold system 10′ is shown including all of the components of threshold system 10, as described above. Additionally, threshold system 10′ includes signal inverter 35. Signal inverter 35 essentially inverts the signal output from control point 14 and then inputs the inverted signal into dynamics processor circuitry 18.

In operation, an input signal enters audio mixing console 12 of threshold system 10′. Control point 14 communicates a control voltage to VCA 20 via control path 22 and control point 14 sends positional inverted data via signal inverter 35 to dynamics processor circuitry 18. The audio input signal is input into dynamics processor circuitry 18 via audio path 26. Dynamics processor circuitry 18 analyzes the signal input via audio path 26 and determines if the signal output level exceeds the threshold of system 10′. The threshold of system 10′ is determined by two factors: the position of control point 14 and the setting of threshold control 25. Thus, as the level of the signal is changed by control point 14, the threshold of system 10′ dynamically changes. For example, if the position of control point 14 is at 0 dB and threshold control 25 is set at +10 dB, dynamics processor circuitry 18 will compress the input signal if it exceeds +10 dB. If the position of control point 14 changes to −5 dB with threshold control 25 set at +10 dB, dynamics processor circuitry 18 will compress the input signal if it exceeds +15 dB due to the action of signal inverter 35. The output from dynamics processor circuitry 18 is returned to audio mixing console 12 via audio path 28 after which the signal is fed to VCA 20. VCA 20 amplifies the signal corresponding to the manipulations of control point 14 after which the signal is fed to output busses for output to speakers or other output producing means.

Although the previous description describes the invention in use with a compressor threshold, the principles of this invention may equally be applied with use of an expander threshold, wherein all signals less than the expander threshold setting are made bigger by the expander ratio amount.

While this invention has been described as having exemplary designs, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

What is claimed is:

1. A method for dynamically controlling a threshold of onset of dynamics processing in an audio dynamics processor, comprising:
controlling an amplitude level of an audio signal;
inputting said amplitude level into the said audio dynamics processor;
inputting a threshold limit into the said audio dynamics processor; and
controlling the threshold of onset of dynamics processing based on said amplitude level and said threshold limit.

2. The method of claim 1, wherein when said amplitude level is increased, the threshold of onset of dynamics processing is increased.

3. The method of claim 1, wherein when said amplitude level is decreased, the threshold of onset of dynamics processing is decreased.

4. The method of claim 1, wherein the said audio dynamics processor comprises an audio compressor.

5. A dynamically-controlled threshold system for dynamically controlling a threshold of onset of dynamics processing, comprising:
an audio mixing console including a control point; and
a dynamics processor in communication with said control point, said dynamics processor having the threshold of onset of dynamics processing controlled by said control point.

6. The system of claim 5, wherein said control point controls an amplitude level of an audio signal, wherein when said control point increases said amplitude level, the threshold of onset of dynamics processing is increased.

7. The system of claim 5, wherein said control point controls an amplitude level of an audio signal, wherein when said control point decreases said amplitude level, the threshold of onset of dynamics processing is decreased.

8. The system of claim 5, wherein said audio mixing console includes a voltage controlled amplifier, said control point in communication with said voltage controlled amplifier.

9. The system of claim 8, wherein said voltage controlled amplifier has an output, said output capable of being processed by said dynamics processor if said output exceeds the threshold of onset of dynamics processing.

10. The system of claim 8, wherein said voltage controlled amplifier has an input, said input capable of being provided by said dynamics processor.

11. The system of claim 10, further comprising a signal inverter, said signal inverter in communication with said control point and said dynamics processor.

12. The system of claim 5, wherein said control point comprises a channel fader.

13. The system of claim 5, wherein said dynamics processor comprises an audio compressor.

14. A dynamically-controlled threshold system for dynamically controlling a threshold of onset of dynamics processing in an audio dynamics processor, comprising:
means for controlling an amplitude level of an audio signal;
means for inputting said amplitude level into the said audio dynamics processor;
means for inputting a threshold limit into the said audio dynamics processor; and
means for controlling the threshold of onset of dynamics processing based on said amplitude level and said threshold limit.

15. The system of claim 14, wherein when said amplitude level is increased, the threshold of onset of dynamics processing is increased.

16. The system of claim 14, wherein when said amplitude level is decreased, the threshold of onset of dynamics processing is decreased.

17. The system of claim 14, further comprising means for amplifying said audio signal, said amplifying means in communication with said means for controlling an amplitude level of an audio signal.

18. The system of claim 17, further comprising means for inverting said amplitude level before inputting said amplitude level into the said audio dynamics processor.

19. The system of claim 14, wherein the said audio dynamics processor comprises an audio compressor.
